(19) United States
(12) Patent Application Publication
(10) Pub. No.: US 2025/0385118 A1
(43) Pub. Date: Dec. 18, 2025

(54) DUAL FORCE LIFT AND GROUND PINS FOR ELECTROSTATIC CHUCK AND METHOD FOR USE THEREOF

(71) Applicant: Axcelis Technologies, Inc., Beverly, MA (US)

(72) Inventors: Paul MENEGHINI, Beverly, MA (US); Vincent Szeto, Beverly, MA (US)

(73) Assignee: Axcelis Technologies, Inc., Beverly, MA (US)

(21) Appl. No.: 19/192,198

(22) Filed: Apr. 28, 2025

Related U.S. Application Data
(60) Provisional application No. 63/646,058, filed on May 13, 2024.

(51) Int. Cl. H01L 21/683; H01J 37/20; H01J 37/317; H01L 21/265

(52) U.S. Cl. CPC H01L 21/6833; H01J 37/20; H01J 37/3171; H01L 21/265; H01J 2237/2007; H01J 2237/20235

(57) ABSTRACT

The disclosure is generally directed to an electrostatic system for processing a workpiece. An exemplary system includes an electrostatic chuck having a surface to receive a workpiece and a circuitry to engage the workpiece to the surface, the surface further comprising at least one opening; a Lift and Ground (LAG) Pin received at the opening of the surface. In certain embodiments, the LAG pin further includes a housing having an exterior and an interior chamber, the housing exterior configured to engage a chuck; a lifting appliance having a lift pin and a lift spring, the lift spring directing the lift pin to provide a bias force away from the housing; and a grounding appliance having a ground pin and a ground spring, the ground pin configured to provide a charge dissipation path form surface.

The instant application claims priority to U.S. Provisional Application Ser. No. 63/646,058, filed May 13, 2024, and entitled “Dual Force Lift And Aground Pins for Electrostatic Chuck and Method for Use Thereof”, the entirety of which is incorporated by reference herein.

### FIELD

The disclosure generally relates to a system, method and apparatus for grounding and lifting a workpiece in an electrostatic chuck. In one embodiment, the disclosure relates to an integrated lift and ground (LAG) pin for use in electrostatic wafer processing.

### BACKGROUND

In manufacturing semiconductor devices, ion implantation is used to selectively introduce impurities into (e.g., dope) a workpiece. The workpiece is typically provided in the form of a substrate such as a silicon, silicon carbide or gallium arsenide wafer. The workpiece is bombarded with impurities or dopants to modify the electrical characteristics or otherwise transform material properties of the substrate. Ion implantation systems are well-known in the semiconductor manufacturing field, as capital equipment utilized to dope workpieces or to form passivation layers during fabrication of an integrated circuit by implanting ions from an ion beam into the workpiece. When used for doping semiconductor wafers, the ion implantation system injects a selected ion species into the workpiece to produce the desired extrinsic material.

The ion implantation system conventionally includes beam forming, steering, deflecting, shaping, filtering and charging subsystems (e.g., beam optical elements or beam optics) positioned between the ion source and the end station. The beam optical elements manipulate and maintain the ion beam along an elongated interior cavity or passageway (e.g., beamline) through which the ion beam passes on route to the end station where the workpiece is positioned. Typically, the workpiece may have an oxide coating thereon (e.g., native oxide). Conventionally, the workpiece is held in place at an electrostatic chuck (ESC) which positions the workpiece in the direct path of ion beam. The ESC builds charge which must be dissipated before and during the ion implantation process in order to avoid the adverse effects of the charge buildup.

The conventional pin design for electrostatic chucks serves two functions: lifting the workpiece off the ESC and grounding the workpiece. Lifting requires enough force to lift the workpiece high enough for the workpiece sense process. Grounding requires enough localized stress to damage the native oxide (i.e., break the oxide coating on the workpiece). The required stress for the grounding is created by applying a lifting force through a sharp tip point of a pin which often results in workpiece damage and other processing anomalies.

There is a need for an improved system, method and apparatus to adequately ground the workpiece and thereafter lift the workpiece from the chuck without damaging the workpiece.

### SUMMARY OF THE DISCLOSURE

The disclosure is generally directed to an integrated lift and ground pins for use in electrostatic wafer processing. In one embodiment, the lift and the ground pins are integrated into a housing and are configured to move and exert force independently of each other.

In one embodiment, the disclosure relates to a dual force action apparatus comprising: a housing having an exterior and an interior chamber, the housing exterior can be configured to engage a chuck; a lifting appliance having a lift pin and a lift spring, the lift spring directing the lift pin to provide a bias force away from the housing; and a grounding appliance having a ground pin, a ground spring and a stop for the ground spring, the grounding appliance configured to provide a charge dissipation path from the surface of the workpiece; wherein the lifting appliance and the grounding appliance slide independently with respect to the housing; and wherein the lifting appliance and the grounding appliance are tunable with respect to each other to independently contact the surface.

In another embodiment, the disclosure relates to a workpiece processing system, comprising: an electrostatic chuck having a surface to receive a workpiece and a circuitry to engage the workpiece to the surface, the surface further comprising at least one opening; a Lift and Ground (LAG) Pin received at the opening of the surface; wherein the LAG pin further comprises: a housing having an exterior and an interior chamber, the housing exterior configured to engage a chuck; a lifting appliance having a lift pin and a lift spring, the lift spring directing the lift pin to provide a bias force away from the housing; and a grounding appliance having a ground pin, a ground spring and a stop for the ground spring, the grounding appliance configured to provide a charge dissipation path from the surface of the workpiece; wherein the lifting appliance and the grounding appliance slide independently with respect to the housing; and wherein the lifting appliance and the grounding appliance are tunable with respect to each other to independently contact the surface.

In still another embodiment, the disclosure relates to a method to engage and disengage a workpiece to an Electrostatic Chuck (ESC) system, the method comprising: electrostatically securing the workpiece to a chuck, the chuck having at least one opening to receive a lift and ground (LAG) pin, the LAG pin further comprising a lifting appliance and a grounding appliance; grounding the workpiece by connecting a ground pin of the grounding appliance to the workpiece, the ground pin configured to dissipate charge from the workpiece; processing the workpiece; and releasing the workpiece from the chuck by activating the lifting appliance to lift the workpiece away from the chuck; wherein the grounding appliance and the lifting appliance are integrated into the LAG pin; and wherein the lifting appliance and the grounding appliance independently exert forces onto the workpiece.

### BRIEF DESCRIPTION OF THE DRAWINGS

Certain disclosed embodiments will now be described with reference to an exemplary ion implantation system as depicted in the accompanying figures, in which like reference numerals may be used to refer to like elements throughout. It should be understood that the description of these aspects is merely illustrative and nonlimiting. In the following description, for purposes of explanation, numerous specific details are set forth in order to provide a thorough understanding of the present invention. It will be evident to one skilled in the art, however, that the present invention may be practiced without some of these specific details. The drawings include:

FIG. 1 illustrates an exemplary architecture for implementing an embodiment of the disclosure;

FIG. 2A illustrates a conventional ground pin;

FIG. 2B is a schematic illustration of a conventional ground pin pressed against a workpiece;

FIG. 3 schematically illustrates an exemplary LAG pin with the ground spring stop integrated with the lift pin housing;

FIG. 4 schematically illustrates an exemplary LAG pin with the ground spring stop integrated with the LAG pin housing;

FIG. 5 schematically illustrates an exploded view of the embodiment of FIG. 4 for visualization of the ground pin subassembly and its installation according to an exemplary implementation;

FIG. 6 schematically illustrates an exemplary LAG pin in the clamped state;

FIG. 7A illustrates an exemplary ESC in the so-called de-clamped state;

FIG. 7B illustrates an exemplary ESC in the clamped state; and

FIG. 8 is a flow diagram representing an exemplary ESC operation according to one embodiment of the disclosure.

### DETAILED DESCRIPTION

In the following description, for purposes of explanation, numerous specific details are set forth in order to provide a thorough understanding of the invention. It will be apparent, however, to one skilled in the art that the invention may be practiced without these specific details. In other instances, structure and devices are shown in block diagram form in order to avoid obscuring the invention. References to numbers without subscripts or suffixes are understood to reference all instances of subscripts and suffixes corresponding to the referenced number. Moreover, the language used in this disclosure has been selected principally for readability and instructional purposes and may not have been selected to delineate or circumscribe the inventive subject matter, resort to the claims being necessary to determine such inventive subject matter. Reference in the specification to “one embodiment” or to “an embodiment” means that a particular feature, structure, or characteristic described in connection with the embodiments is included in at least one embodiment of the invention, and multiple references to “one embodiment” or “an embodiment” should not be understood as necessarily all referring to the same embodiment.

The embodiments described herein are examples and for illustrative purposes.

Persons of ordinary skill in the art will recognize that alternative techniques for implementing the disclosed subject matter may be used. Elements of example embodiments may be arranged in different arrangements or combined with elements of different example embodiments. For example, the order of execution of blocks and flow charts may be changed. Some of the blocks of those flowcharts may be changed, eliminated, or combined and other blocks may be added as desired.

Ion implantation is a physical process and is employed in semiconductor device fabrication to selectively implant dopant into a workpiece. The workpiece may comprise a wafer. The workpiece material is typically a semiconductor based substance. Ion implantation generally does not rely on a chemical interaction between a dopant and semiconductor material. During the ion implantation process, dopant atoms/molecules from an ion source of an ion implanter (or source material) are ionized, accelerated, formed into an ion beam, analyzed, and swept across a workpiece or the workpiece is translated through the ion beam. Ion sources typically generate the ion beam by ionizing a source material in an are chamber, wherein a component of the source material is a desired dopant element. The desired dopant element is then extracted from the ionized source material in the form of the ion beam. The dopant ions physically bombard the workpiece to enter the surface and come to rest below the surface at a depth related to their energy. The workpiece is held in place throughout the implementation process through the use of an electrostatic force.

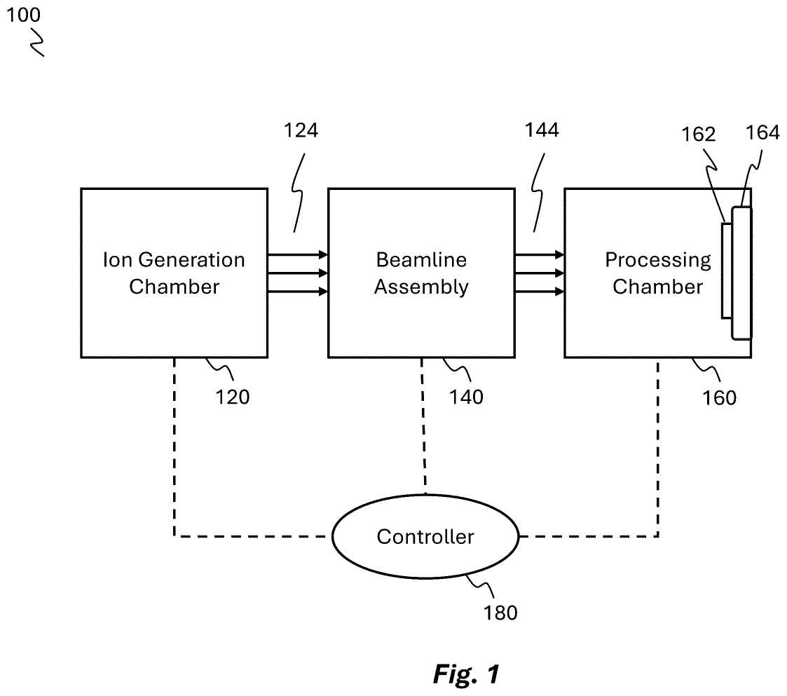

FIG. 1 is a representative system architecture of an ion implantation system according to certain disclosed embodiments. System 100 of FIG. 1 has been significantly simplified to illustrate an environment for implementing the disclosed principles. A detailed description of the system architecture can be found at U.S. Pat. No. 10,395,889 B2, which is incorporated herein by reference for background information.

Referring to FIG. 1, ion generation chamber 120 comprises systems, components and subassemblies to generate charged ions that are then extracted and formed into ion beam 124. To generate the ions, precursor material to be ionized is provided within generation chamber 120. The dopant material can be introduced directly in the form of a precursor gas which can, for example, be fed into chamber 120 from a gas, liquid or vaporized solid source (not shown) or may be formed by sputtering a target in chamber 120 using non-dopant ions generated from another, typically inert, input gas. A number of suitable mechanisms (none of which are shown) may be used to excite free electrons within ion generation chamber 120, such as: RF or microwave excitation sources; electron beam injection sources; electromagnetic sources; and/or a cathode which creates an arc discharge within the chamber, to name a few. The excited electrons collide with the precursor gas molecules to generate ions. Generally, positive ions are selected for implantation although the disclosure herein is equally applicable to systems wherein negative ions are generated.

Ions generated in chamber 120 are extracted and directed as ion beam 124 along a path to beamline assembly 140. Beamline assembly 140 comprises components, systems and subassemblies to, among others, analyze, steer, filter and focus and beam line 124 to processed beamline 144. Processing chamber 160 includes, among others, vacuum environment and an electrostatic chuck 164 to receive and retain workpiece 162 stationary during processing, Processing chamber may include components and subassemblies to robotically receive and place workpiece 162 at a precise location with respect to chuck 164. Processed beamline 144 is directed to workpiece 162 to initiate the ion implantation process. The interaction of the various components of system 100 are orchestrated through a vast control network which is schematically represented as controller 180 in FIG. 1. Once the process is completed, workpiece 162 must be released from chuck 164 and retrieved from processing chamber 160. A lifting pin has been conventionally used to release workpiece 162 from chuck 164.

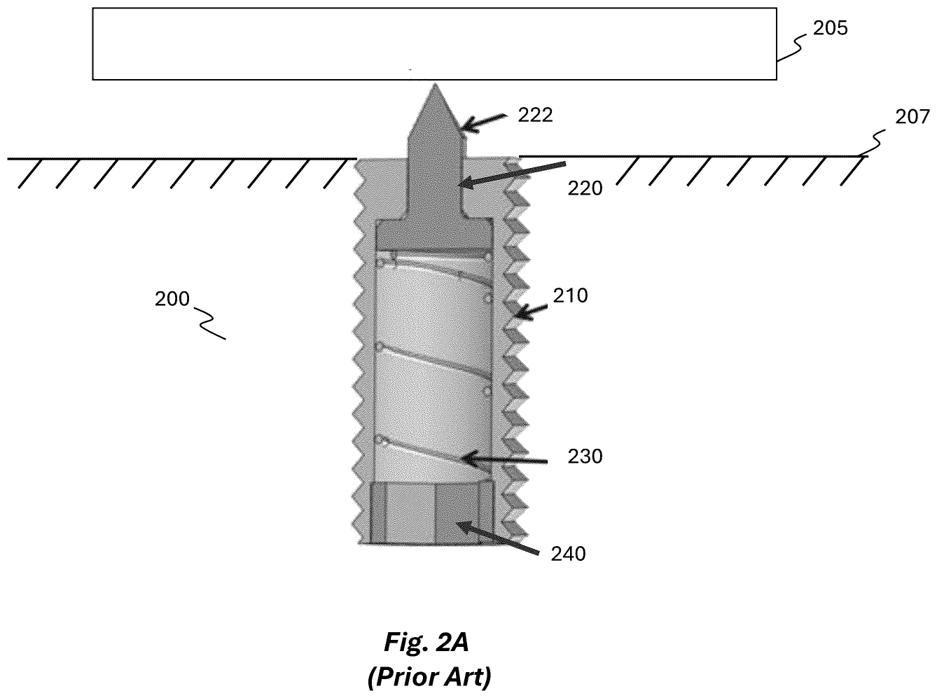

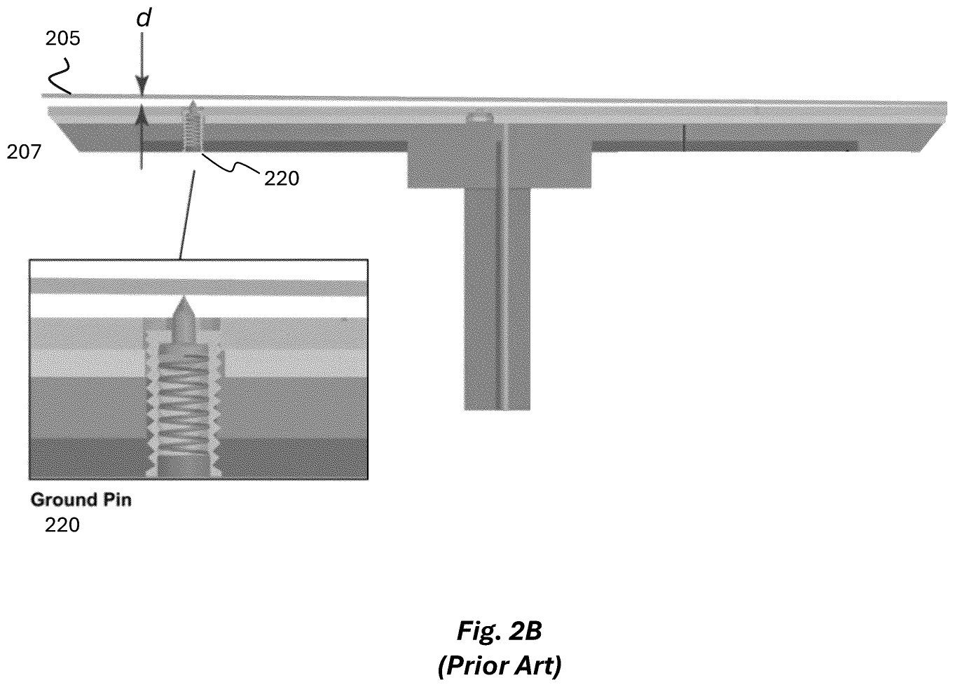

FIG. 2A illustrates a conventional ground pin against workpiece 205. Ground pin 200 includes ground pin housing 210, ground pin 220, ground pin tip 222, internal lifting coil spring 230 and stopper 240. Housing 210 is threaded so as to mate to electrostatic chuck 207. Coil spring 230 functions to apply the force necessary to both lift workpiece 205 from chuck 207 and to ground the workpiece. When ESC circuit (not shown) is engaged through a controller (e.g., controller 180, FIG. 1), chuck 205 pushes pin 220 down and coil spring 230 is compressed within housing 210 such that workpiece 205 rests against chuck surface 207. In contrast, when the ESC circuit (not shown) is disengaged, pin tip 222 pushes against chuck 205 thereby lifting workpiece 205 away from housing 220 and chuck surface 207 as shown in FIG. 2A.

FIG. 2B is a schematic illustration of a conventional ground pin pressed against a workpiece. In FIG. 2A, ground pin 220 is integrated into ESC 207 and grounds workpiece 205 through the ground pin (see exploded view). As illustrated, ground pin 220 lifts portion of workpiece 205 away from ESC 207 by distance d. The conventional ground pin 200 has a shortcoming in that both the lifting and the grounding functions use the same force which in turn limits the ability to optimize each function. In some applications, the minimum force required to lift the workpiece damages workpiece 205 which leads to yield issues in the subsequent processing steps. Minimizing the lifting force leads to other reliability issues in manufacturing as well as in the workpiece lifting operation.

The disclosed principles address these and other problems of the conventional ground pin. In one embodiment, the forces driving the lifting and the grounding mechanisms are decoupled such that each function may be implemented independently of the other function. Among other benefits, the decoupling of the forces allows the grounding pin to exert a smaller force as compared to the lifting spring while maintaining a grounding function. The decoupling of forces also allows the lifting pin to provide adequate force to lift the workpiece without leaving a ground pin imprint or inducing other damage to the workpiece.

In one application of the exemplary principles, a “lift-and-ground” (LAG) pin design may be considered as a smaller grounding mechanism (interchangeably, appliance) positioned inside a lifting pin mechanism such that the ground pin tip can move independently of the lift pin tip. The larger mechanism which occupies the outside diameter (i.e., the lifting mechanism), may comprise a large, flat surface or a softer material (e.g., than the workpiece) to minimize the stress on the workpiece.

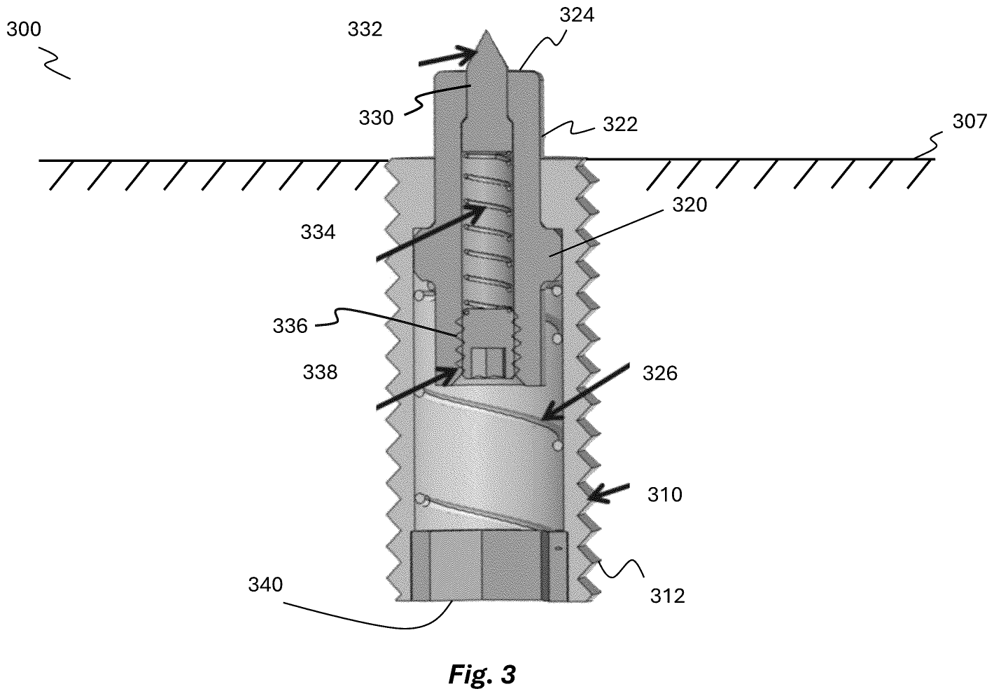

FIG. 3 schematically illustrates an exemplary LAG pin with a ground spring mechanism integrated within a lift pin housing. Specifically, FIG. 3 shows LAG pin 300 having LAG pin housing 310 with LAG pin threads 312. LAG pin threads 312 allow placement of LAG pin 300 with respect to chuck 307.

A lift pin mechanism is positioned inside the LAG pin housing 310. The lift pin mechanism includes lift pin housing 320, lift pin tip 322 having a top surface 324, lift pin spring 326 and stopper 340. The lift pin mechanism can move relative to the LAG pin housing 310 due to the lift pin spring 326 which exerts a directional bias force against stopper 340 and the lift pin housing 320. Stopper 340 may be movably engaged with respect to LAG pin housing 310. Among others, the engagement allows adjusting the applied force to the lift pin spring. In another embodiment, stopper 340 may be welded in position to LAG pin housing 310. While lift pin spring 326 is shown as a coil spring, other modes of exerting directional force may be used without departing from the disclosed principles.

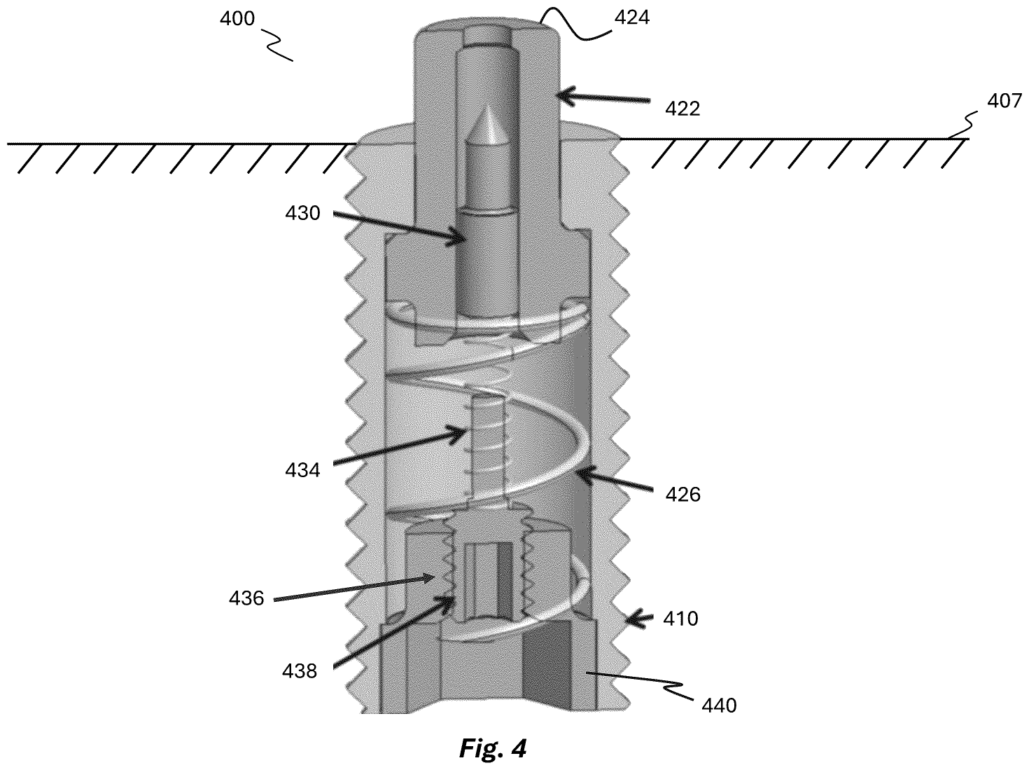

The grounding mechanism of LAG pin 300 includes ground pin body 330 having ground pin tip 332, ground spring 334, tuning threads 336 and ground pin stop 338. Ground pin tip 332 is configured to contact to the workpiece (not shown in FIG. 3) to provide the electrical grounding function. Ground pin body 330 moves inside lift pin housing 320 by the virtue of ground pin spring 334. In the embodiment of FIG. 3, ground pin spring 334 rests against ground pin spring stopper 338. Threads 336 may be optionally included to provide further adjustment (i.e., tuning) of the ground pin force, for example, by reducing the travel distance (or increasing compression) of the ground pin spring. Ground pin tip 332 may comprise a sharp tip designed to break the native oxide layer of the workpiece to ground the workpiece. Ground pin spring 334 needs enough force to establish the oxide breaking and grounding functions without damaging the workpiece. While the disclosed principles are not limited thereto, the embodiment of FIG. 4 shows a concentric mechanism.

The illustrated embodiment of FIG. 3 provides a number of advantages over the conventional ground pins. For example, the disclosed embodiment allows for further adjustment of the LAG pin relative to the chuck surface, independent movement of the lift pin 320 and ground pin body 330, independent spring forces for lift pin spring 326 and ground pin spring 334 and additional tunability of the ground pin relative to the lift pin.

In the embodiment of FIG. 3, the geometry of lift pin 324 is substantially flat. As a result, stress imparted on the workpiece from the lifting force to detach the workpiece (not shown) from the ESC (not shown) is low and will not damage the workpiece. Importantly, the size of the LAG pin housing 310 and its threading 312 may be selected such that the disclosed embodiments can be retrofitted to an existing ESC without modifying the latter.

In one embodiment, lift pin tip 322 may be made of a softer material to minimize any local stress imparted on the workpiece from imperfections in flatness or alignment. Lift pin housing 320 must also be electrically conductive to establish a ground path for the ground pin body 330 to the LAG pin housing 310. An exemplary material may include a conductive thermoplastic including, Polyimide Resin (e.g., made by DuPont Corp. under tradename Vespel™), Polyetherimide (Ultem™) or Polyether ether ketone (PEEK). The force of the lift pin tip 322 can be established by the spring rate and the compression length of the lift pin spring 326. In one embodiment, the initial compression of the spring may be large enough such that it does not change significantly with the actuation length of lift pin tip 322. The height of lift pin tip 322 reaching above the ESC (not shown) surface may be adjusted by the installing LAG pin 300 into the ESC (not shown) such that its maximum height is limited by the LAG pin housing 310 and the lift pin tip 322. In other words, LAG pin threads 312 may be used to adjust the maximum reach of lift pin 322 relative to the surface of the ESC (not shown).

As stated, ground pin tip 332 may optionally break through an oxide layer on the workpiece. In certain embodiments, ground pin tip 332 comprises a conductive material to function as a grounding mechanism. The material may be relatively hard to minimize damage and deterioration on ground pin tip 332 which may become dulled due to extended use. Exemplary material for ground pin tip 332 (and optionally ground body 330) may include tungsten or silicon carbide. The height of the ground pin tip 332 extending above the lift pin top surface 324 may be established by a geometric stop from the shape of lift pin tip 322 and the ground pin tip 332. In the embodiment of FIG. 3, the ground pin is always in contact with the workpiece and the force is independent of the height adjustment of lift pin 322.

FIG. 4 schematically illustrates an exemplary LAG pin with the ground spring stop integrated with the LAG pin housing, according to another embodiment. Specifically, FIG. 4 shows LAG pin 400 having LAG pin threaded housing 410 integrated with chuck 407. Lag pin housing 410 has a hollow interior which concentrically houses a lifting mechanism and a grounding mechanism. The lifting mechanism includes lift pin tip 422 having a lift pin top surface 424. Lift pin tip 422 is pushed upward by lift pin spring 426. The grounding mechanism comprises ground pin body 430, ground pin spring 434 and ground pin spring stop 438. Ground spring stop 438 may comprise additional tuning threads 436 configured to accommodate the compression and movement of springs 426 and 434. In FIG. 4, such tuning may be optionally exercised to affect the ground pin's movement and compression independently of the lift pin mechanism thus allowing for a larger travel for lift pin 422 as compared with other embodiments. Ground spring stop 438 rests against stopper 440. In contrast with the exemplary embodiment of FIG. 3, the lift pin tip 422 may comprise non-conductive material as the ground path is not established through lift pin tip 422.

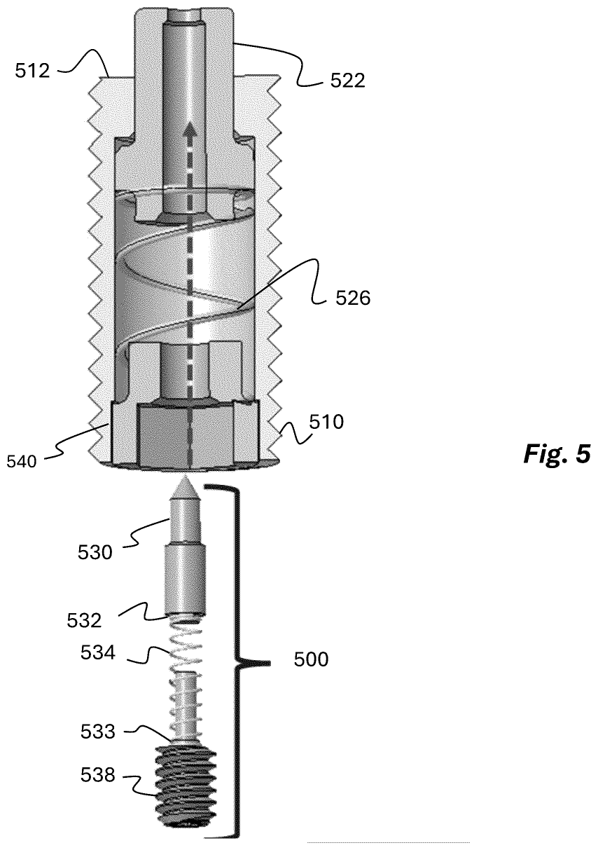

FIG. 5 schematically illustrates an exploded view of the embodiment of FIG. 4 for visualization of the ground pin subassembly and its installation according to an exemplary implementation. In FIG. 5, threaded LAG pin housing 510 comprises a hollow interior to receive the lift pin mechanism. The lift pin mechanism includes lift pin tip 522 which is pushed up against the housing via lift pin spring 526. Spring stop 540 may be optionally intergraded into spring stop 540 or may be removably assembled thereto. The ground pin tip 530, ground pin spring 534 and ground pin spring stop 538 may be held together as ground pin subassembly via friction on the inner diameter of spring 534 and bosses 532 and 533. In one application, subassembly 500 may be installed into LAG pin housing 510 after lift pin tip 522 is assembled into the LAG pin housing. The ground pin spring stop 538 may comprise a threaded body to facilitate assembly. The ground pin spring stop 538 may optionally include an extension body along the interior of the spring (as shown) to prevent buckling of any unconstrained length of spring 534. In certain implementations, subassembly 500 may be installed in LAG pin housing 510 such that the ground pin tip 530 is above the top of LAG pin housing 512 but below the top of lift pin tip 424 (FIG. 4).

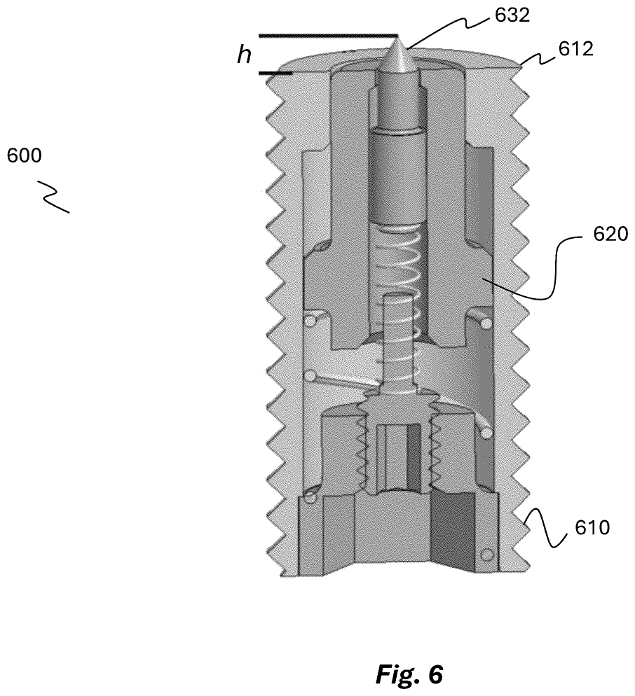

FIG. 6 schematically illustrates an exemplary LAG pin 600 in the clamped state. In FIG. 6, LAG pin housing 610 includes the lifting mechanism and the grounding mechanism incorporated therein. Notably, the assembled structure shows lifting mechanism 620 which sits flush with the top of the LAG pin housing 610. LAG pin 600 also shows ground pin 632 protruding beyond housing top surface 612 by distance h. In the embodiment of FIG. 6, the LAG pin 600 is assumed to be installed with the top of the LAG pin housing 612 flush to the ESC surface (not shown). The distance h between the top of the top of the ground pin 632 to the top of LAG pin housing tip 612 may comprise the deflection that the ground pin spring will see when the workpiece (not shown) is clamped to the chuck (not shown). Distance h may be adjusted and calibrated during the assembly to produce the desired ground pin force exerted on the workpiece. In FIG. 6, when the workpiece is clamped to the ECS, the ground pin tip is engaged with the workpiece to establish ground. When the workpiece is unclamped from the ESC, the lift pin tip pushes workpiece completely off the ESC and the ground pin tip.

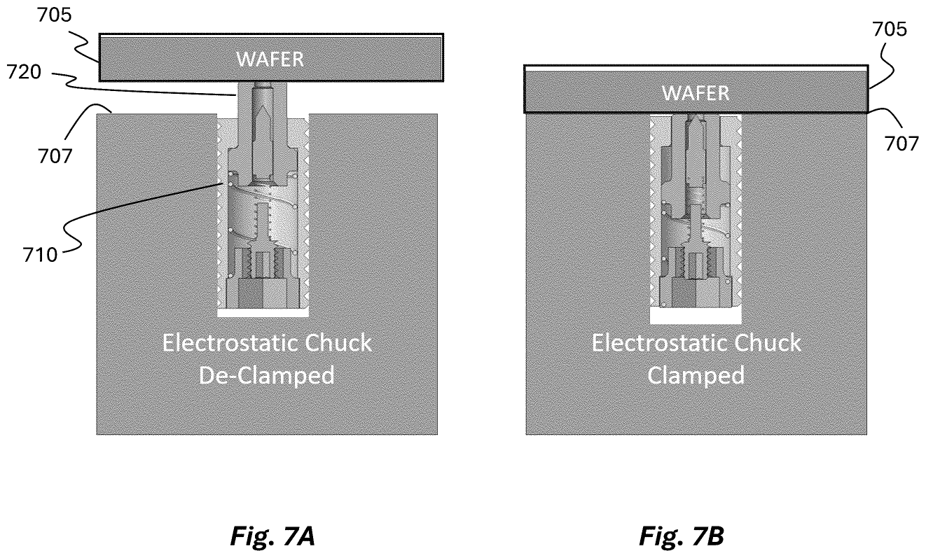

FIG. 7A illustrates an exemplary ESC in the so-called de-clamped state. Here, workpiece 705 is lifted above ESC surface 707 via the release force exerted by lift pin 720. Ground pin housing 710 is shown as integrated with the ESC 707. FIG. 7B illustrates an exemplary ESC in the clamped state in which workpiece 705 is in contact with ESC surface 707. Here, the electrostatic forces are engaged to compress the lifting mechanism, engage the ground pin mechanism and clamp down the workpiece onto the chuck.

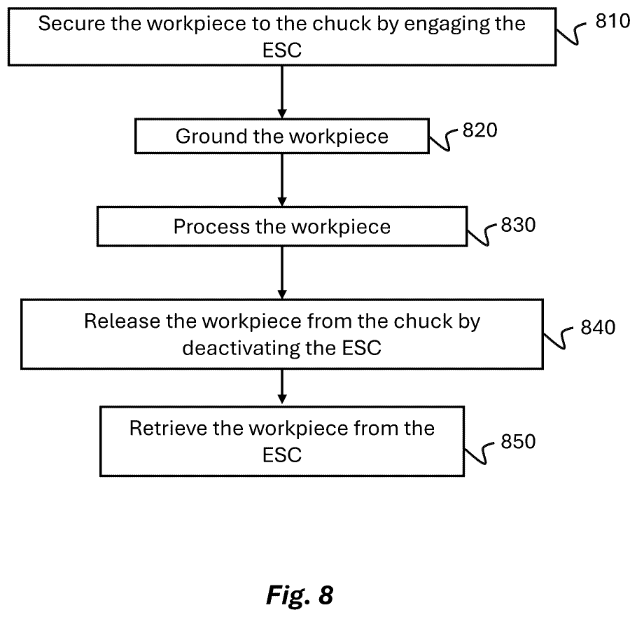

FIG. 8 is an operation flow for implementing an exemplary embodiment of the disclosure. FIG. 8 starts with operation 810 in which the workpiece is secured to the chuck by engaging the electrostatic circuit of the ESC system. In an exemplary embodiment, the ESC surface may comprise at least one opening to receive a LAG pin having an independent lifting appliance and a grounding appliance. At operation 820, the grounding appliance is connected (e.g., through a ground pin and a biasing spring) to the workpiece in order to dissipate charge and ground the workpiece. At operation 830 the workpiece is processed. In one embodiment, processing the workpiece may comprise ion implantation. At operation 840 and upon termination of the processing operation, the workpiece is released from the chuck. In one application, the workpiece is released from the chuck by disengaging the electrostatic circuit of the ESC system. The releasing operation may comprise activating a lifting application having a lift pin biased by a lift spring whereby the lift spring pushes the lift pin to detach the workpiece from the chuck. At operation 850, the workpiece is retrieved from the chuck.

### Exemplary Embodiments

The following examples are provided to further illustrate the disclosed principles. The examples are non-limiting and demonstrative.

Example 1 relates to a workpiece processing system, comprising: an electrostatic chuck having a surface to receive a workpiece and a circuitry to engage the workpiece to the surface, the surface further comprising at least one opening; a Lift and Ground (LAG) Pin received at the opening of the surface; wherein the LAG pin further comprises: a housing having an exterior and an interior chamber, the housing exterior configured to engage a chuck; a lifting appliance having a lift pin and a lift spring, the lift spring directing the lift pin to provide a bias force away from the housing; and a grounding appliance having a ground pin and a ground spring, the ground pin configured to provide a charge dissipation path from the surface of the work piece; wherein the lifting appliance and the grounding appliance slide independently with respect to the housing; and wherein the lifting appliance and the grounding appliance are tunable with respect to each other to independently contact the surface.

Example 2 relates to the workpiece processing system of Example 1, wherein the circuitry is further configured to disengage the workpiece from the surface.

Example 3 relates to the workpiece processing system of Example 1, wherein the lift spring provides a non-linear force.

Example 4 relates to the workpiece processing system of Example 1, wherein the lifting appliance and the grounding appliance are concentrically positioned within the interior chamber of the housing.

Example 5 relates to the workpiece processing system of Example 1, wherein the lift spring exerts a higher biasing force relative to the ground spring.

Example 6 relates to the workpiece processing system of Example 1, wherein the lift pin material is softer than the workpiece material.

Example 7 relates to the workpiece processing system of Example 1, wherein the lifting appliance and the grounding appliance are tunable to engage the ground pin to the surface when the lifting appliance is at a compressed state.

Example 8 relates to the workpiece processing system of Example 1, wherein at least one of the lifting appliance or the tuning appliance further comprises a tuning feature to connect the ground pin to the surface when the lifting appliance is at a compressed state.

Example 9 relates to the workpiece processing system of Example 8, wherein the tuning feature comprises a plurality of threads.

Example 10 relates to the workpiece processing system of Example 1, wherein the chuck comprises an electrostatic chuck (ESC) configured to receive a workpiece and wherein the housing is configured to engage the (ESC) and thereby contact one or more of the lift pin or the ground pin to the workpiece.

Example 11 relates to a dual action apparatus, comprising: a housing having an exterior and an interior chamber, the housing exterior configured to engage a chuck; a lifting appliance having a lift pin and a lift spring, the lift spring configured to cause the lift pin to provide a bias force to a workpiece disposed on the chuck in a direction away from the housing; and a grounding appliance having a ground pin and a ground spring, the ground pin configured to provide a charge dissipation path from a surface of the workpiece; wherein the lifting appliance and the grounding appliance are independently movable with respect to the housing; and wherein the lifting appliance and the grounding appliance are tunable with respect to each other to independently contact and control the bias force applied to the surface of the workpiece.

Example 12 relates to the apparatus of Example 11, wherein the lift spring provides a linear force.

Example 13 relates to the apparatus of Example 11, wherein the lift spring provides a non-linear force.

Example 14 relates to the apparatus of Example 11, wherein the lifting appliance and the grounding appliance are concentrically positioned within the interior chamber of the housing.

Example 15 relates to the apparatus of Example 11, wherein the lift spring exerts a higher biasing force relative to the ground spring.

Example 16 relates to the apparatus of Example 11, wherein the lift pin comprises a softer material than the workpiece material.

Example 17 relates to the apparatus of Example 11, wherein the lifting appliance and the grounding appliance are tunable to engage the ground pin to the surface when the lifting appliance is at a compressed state.

Example 18 relates to the apparatus of Example 11, wherein at least one of the lifting appliance or the tuning appliance further comprises a tuning feature to connect the ground pin to the surface when the lifting appliance is at a compressed state.

Example 19 relates to the apparatus of Example 18, wherein the tuning feature comprises a plurality of threads.

Example 20 relates to the apparatus of Example 11, wherein the chuck comprises an electrostatic chuck (ESC) configured to receive the workpiece and wherein the housing is configured to engage the ESC and thereby contact one or more of the lift pin or the ground pin to the workpiece.

Example 21 relates to the apparatus of Example 11, wherein a top surface of the lift pin is flat, and wherein the ground pin comprises a sharp tip configured to break a native oxide layer of the workpiece so as to provide the charge dissipation path from the surface of the workpiece.

Example 22 relates to a method to engage and disengage a workpiece to an Electrostatic Processing Chuck (ESC) system, the method comprising: electrostatically securing the workpiece to a chuck, the chuck having at least one opening to receive a lift and ground (LAG) pin, the LAG pin further comprising a lifting appliance and a grounding appliance; grounding the workpiece by connecting a ground pin of the grounding appliance to the workpiece, the ground pin configured to dissipate charge from the workpiece; processing the workpiece; and releasing the workpiece from the chuck by activating the lifting appliance to lift the workpiece away from the chuck; wherein the grounding appliance and the lifting appliance are integrated into the LAG pin; and wherein the lifting appliance and the grounding appliance independently exert forces onto the workpiece.

Example 23 relates to the method of Example 22, wherein the grounding appliance further comprises a ground spring configured to connect the ground pin to the workpiece.

Example 24 relates to the method of Example 22, wherein electrostatically securing the workpiece to the chuck further comprises engaging an electrostatic circuit of the ESC system and wherein releasing the workpiece further comprises disengaging the electrostatic circuit of the ESC system.

Example 25 relates to the method of Example 22, the lifting appliance comprises a lift pin and a lift spring, wherein the lift spring directs the lift pin to lift the workpiece away from the chuck.

Example 26 relates to the method of Example 22, wherein the LAG pin further comprises a housing and wherein the housing is integrated with the chuck.

Example 27 relates to the method of Example 22, wherein the workpiece comprises a wafer and wherein processing the workpiece comprises ion implantation.

Example 28 relates to the method of Example 22, wherein the lifting appliance and the grounding appliance are tunable with respect to independently apply force to the workpiece.

While the principles of the disclosure have been illustrated in relation to various illustrative and exemplary embodiments, the principles of the disclosure are not limited thereto and include any modification, variation or permutation thereof.

What is claimed is:

1. A workpiece processing system, comprising:
an electrostatic chuck having a surface to receive a workpiece and a circuitry to engage the workpiece to the surface, the surface further comprising at least one opening;
a Lift and Ground (LAG) Pin received at the opening of the surface;
wherein the LAG pin further comprises:
a housing having an exterior and an interior chamber, the housing exterior configured to engage a chuck;
a lifting appliance having a lift pin and a lift spring, the lift spring directing the lift pin to provide a bias force away from the housing; and
a grounding appliance having a ground pin and a ground spring, the ground pin configured to provide a charge dissipation path from the surface of the work piece;
wherein the lifting appliance and the grounding appliance slide independently with respect to the housing; and
wherein the lifting appliance and the grounding appliance are tunable with respect to each other to independently contact the surface.

2. The workpiece processing system of claim 1, wherein the circuitry is further configured to disengage the workpiece from the surface.

3. The workpiece processing system of claim 1, wherein the lift spring provides a non-linear force.

4. The workpiece processing system of claim 1, wherein the lifting appliance and the grounding appliance are concentrically positioned within the interior chamber of the housing.

5. The workpiece processing system of claim 1, wherein the lift spring exerts a higher biasing force relative to the ground spring.

6. The workpiece processing system of claim 1, wherein the lift pin material is softer than the workpiece material.

7. The workpiece processing system of claim 1, wherein the lifting appliance and the grounding appliance are tunable to engage the ground pin to the surface when the lifting appliance is at a compressed state.

8. The workpiece processing system of claim 1, wherein at least one of the lifting appliance or the tuning appliance further comprises a tuning feature to connect the ground pin to the surface when the lifting appliance is at a compressed state.

9. The workpiece processing system of claim 8, wherein the tuning feature comprises a plurality of threads.

10. The workpiece processing system of claim 1, wherein the chuck comprises an electrostatic chuck (ESC) configured to receive a workpiece and wherein the housing is configured to engage the ESC and thereby contact one or more of the lift pin or the ground pin to the workpiece.

11. A dual action apparatus, comprising:
a housing having an exterior and an interior chamber, the housing exterior configured to engage a chuck;
a lifting appliance having a lift pin and a lift spring, the lift spring configured to cause the lift pin to provide a bias force to a workpiece disposed on the chuck in a direction away from the housing; and
a grounding appliance having a ground pin and a ground spring, the ground pin configured to provide a charge dissipation path from a surface of the workpiece;
wherein the lifting appliance and the grounding appliance are independently movable with respect to the housing; and
wherein the lifting appliance and the grounding appliance are tunable with respect to each other to independently contact and control the bias force applied to the surface of the workpiece.

12. The apparatus of claim 11, wherein the lift spring provides a linear force.

13. The apparatus of claim 11, wherein the lift spring provides a non-linear force.

14. The apparatus of claim 11, wherein the lifting appliance and the grounding appliance are concentrically positioned within the interior chamber of the housing.

15. The apparatus of claim 11, wherein the lift spring exerts a higher biasing force relative to the ground spring.

16. The apparatus of claim 11, wherein the lift pin comprises a softer material than the workpiece material.

17. The apparatus of claim 11, wherein the lifting appliance and the grounding appliance are tunable to engage the ground pin to the surface when the lifting appliance is at a compressed state.

18. The apparatus of claim 11, wherein at least one of the lifting appliance or the tuning appliance further comprises a tuning feature to connect the ground pin to the surface when the lifting appliance is at a compressed state.

19. The apparatus of claim 18, wherein the tuning feature comprises a plurality of threads.

20. The apparatus of claim 11, wherein the chuck comprises an electrostatic chuck (ESC) configured to receive the workpiece and wherein the housing is configured to engage the ESC and thereby contact one or more of the lift pin or the ground pin to the workpiece.

21. The apparatus of claim 11, wherein a top surface of the lift pin is flat, and wherein the ground pin comprises a sharp tip configured to break a native oxide layer of the workpiece so as to provide the charge dissipation path from the surface of the workpiece.

22. A method to engage and disengage a workpiece to an Electrostatic Processing Chuck (ESC) system, the method comprising:
electrostatically securing the workpiece to a chuck, the chuck having at least one opening to receive a lift and ground (LAG) pin, the LAG pin further comprising a lifting appliance and a grounding appliance;
grounding the workpiece by connecting a ground pin of the grounding appliance to the workpiece, the ground pin configured to dissipate charge from the workpiece;
processing the workpiece; and
releasing the workpiece from the chuck by activating the lifting appliance to lift the workpiece away from the chuck;
wherein the grounding appliance and the lifting appliance are integrated into the LAG pin; and
wherein the lifting appliance and the grounding appliance independently exert forces onto the workpiece.

23. The method of claim 22, wherein the grounding appliance further comprises a ground spring configured to connect the ground pin to the workpiece.

24. The method of claim 22, wherein electrostatically securing the workpiece to the chuck further comprises engaging an electrostatic circuit of the ESC system and wherein releasing the workpiece further comprises disengaging the electrostatic circuit of the ESC system.

25. The method of claim 22, the lifting appliance comprises a lift pin and a lift spring, wherein the lift spring directs the lift pin to lift the workpiece away from the chuck.

26. The method of claim 22, wherein the LAG pin further comprises a housing and wherein the housing is integrated with the chuck.

27. The method of claim 22, wherein the workpiece comprises a wafer and wherein processing the workpiece comprises ion implantation.

28. The method of claim 22, wherein the lifting appliance and the grounding appliance are tunable with respect to independently apply force to the workpiece.
